(19) United States
(12) Patent Application Publication
(10) Pub. No.: US 2026/0322420 A1
(43) Pub. Date: Oct. 15, 2026

(54) FILTER WITH LOW INSERTION LOSS AND NEAR-CHANNEL REJECTION

(71) Applicant: Qorvo US, Inc., Greensboro, NC (US)

(72) Inventors: Scott Muir, Knoxville, TN (US); Chris Levesque, Fountain Valley, CA (US); Manuel Elias, Fern Park, FL (US)

(21) Appl. No.: 19/539,477

(22) Filed: Feb. 13, 2026

Related U.S. Application Data
(60) Provisional application No. 63/831,367, filed on Jun. 27, 2025.
(60) Provisional application No. 63/785,769, filed on Apr. 9, 2025.

(51) Int. Cl. H04B 1/525; H03H 9/60; H03H 9/64; H03H 9/70

(52) U.S. Cl. CPC H04B 1/525; H03H 9/605; H03H 9/6483; H03H 9/706

(57) ABSTRACT

Filters with low insertion loss and near-channel rejection, along with methods for use, are disclosed. In one aspect, a multi-stage filter is made with acoustic resonators being used to form sections within a given stage. The stages are separated by a match circuit. By relying on stages instead of just sections, overall insertion loss is maintained at acceptable levels while getting deep rejection of adjacent channels. Such a filter profile has wide application in wireless systems, with particular use in Wi-Fi.

### RELATED APPLICATIONS

The present application is related to U.S. Provisional Patent Application Serial No. 63/785,769, filed on Apr. 9, 2025, and entitled “NOTCH FILTER WITH LOW INSERTION LOSS AND HIGH REJECTION,” and U.S. Provisional Application Serial No. 63/831,367, filed on Jun. 27, 2025, and entitled “FILTER WITH LOW INSERTION LOSS AND NEAR-CHANNEL REJECTION,” the contents of which are incorporated herein by reference in their entirety.

### BACKGROUND

### I. Field of the Disclosure

The technology of the disclosure relates generally to filters and, more particularly, to filters that have low insertion loss and high adjacent channel rejection, such as may be required in multiband Wi-Fi systems.

### II. Background

Computing devices abound in modern society, and more particularly, mobile or wireless communication devices have become increasingly common. The prevalence of these mobile communication devices is driven in part by the many functions that are now enabled on such devices. Increased processing capabilities in such devices mean that mobile communication devices have evolved from pure communication tools into sophisticated mobile entertainment centers, thus enabling enhanced user experiences. Various wireless protocols have evolved to serve these mobile or wireless communication devices, including various cellular standards as well as shorter-range protocols such as Wi-Fi or Bluetooth. Commercial pressure for increased bandwidth has resulted in these standards providing additional channels that may be frequency-proximate to existing channels on the electromagnetic spectrum. Finding ways for these channels to coexist provides room for innovation.

### SUMMARY

Aspects disclosed in the detailed description include filters with low insertion loss and near-channel rejection, along with methods for using same. In particular, aspects of the present disclosure contemplate a multi-stage filter made with acoustic resonators being used to form sections within a given stage. The stages are separated by a match circuit. By relying on stages instead of just sections, overall insertion loss is maintained at acceptable levels while getting deep rejection of adjacent channels. Such a filter profile has wide application in wireless systems, with particular use in Wi-Fi.

In this regard, in one aspect, a filter is disclosed. The filter includes an input, a first filter section, a mid-match circuit, the first filter section serially coupled between the input and the mid-match circuit, a second filter section, and an output, the second filter section serially coupled between the mid-match circuit and the output.

In another aspect, a wireless communication device is disclosed. The wireless communication device includes a first transceiver configured to operate at a first frequency, a first antenna coupled to the first transceiver and configured to transmit first signals from the first transceiver, and a second transceiver configured to operate at a second frequency. The wireless communication device also includes a second antenna coupled to the second transceiver and configured to transmit second signals from the second transceiver, where second signals from the second antenna may impinge on the first antenna and be received therethrough; and a filter associated with the first antenna. The filter includes an input, a first filter section, a mid-match circuit, the first filter section serially coupled between the input and the mid-match circuit, a second filter section, and an output, the second filter section serially coupled between the mid-match circuit and the output.

In another aspect, a method for filtering a signal is disclosed. The method includes providing a signal at an input, filtering the signal with a first filter section, performing an impedance match with a mid-match circuit on a filtered signal from the first filter section, filtering a matched signal from the mid-match circuit with a second filter section, and outputting a final signal from the second filter section.

### BRIEF DESCRIPTION OF THE DRAWINGS

FIG. 1 is a block diagram of a wireless router that may use adjacent channels;

FIG. 2A is a circuit diagram of a filter stage made from inductors (L) and capacitors (C);

FIG. 2B is a circuit diagram of a filter stage made from acoustic resonators;

FIG. 2C is a graph of filter response versus frequency for a filter made from the stages of FIGS. 2A or 2B;

FIG. 3 is a block diagram of a filter according to aspects of the present disclosure;

FIG. 4 is a circuit diagram of the filter of FIG. 3;

FIG. 5 is a circuit diagram of a more general filter where each stage may have multiple sections;

FIG. 6A is a front side perspective view of an acoustic die on a laminate according to an aspect of the present disclosure;

FIG. 6B is a front side perspective view of an acoustic die on a laminate according to another aspect of the present disclosure; and

FIG. 7 is a flowchart illustrating an exemplary process for using a filter according to aspects of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a," “an,” and “the” are intended to include the plural forms as well unless the context clearly indicates otherwise. It will be further understood that the terms “comprises," “comprising," “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include filters with low insertion loss and near-channel rejection, along with methods for using same. In particular, aspects of the present disclosure contemplate a multi-stage filter made with acoustic resonators being used to form sections within a given stage. The stages are separated by a match circuit. By relying on stages instead of just sections, overall insertion loss is maintained at acceptable levels while getting deep rejection of adjacent channels. Such a filter profile has wide application in wireless systems, with particular use in Wi-Fi.

While most of the discussion below is phrased in terms of a bandpass filter, it should be appreciated that the concepts may also apply to a notch filter and may be able to reach greater than 60 dB of near-band rejection without impacting insertion loss. Thus, whether the filter is contemplated as being a bandpass filter with good adjacent-channel rejection or a notch filter whose notch corresponds to adjacent channels, the end goal is still to allow signals of interest to pass while rejecting signals or harmonics in nearby adjacent channels.

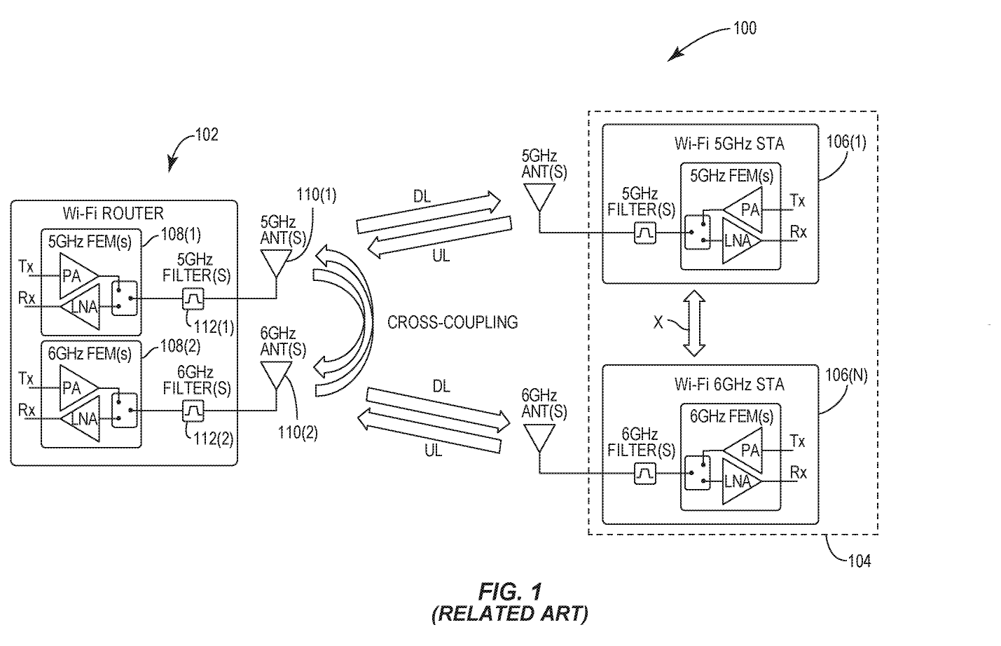

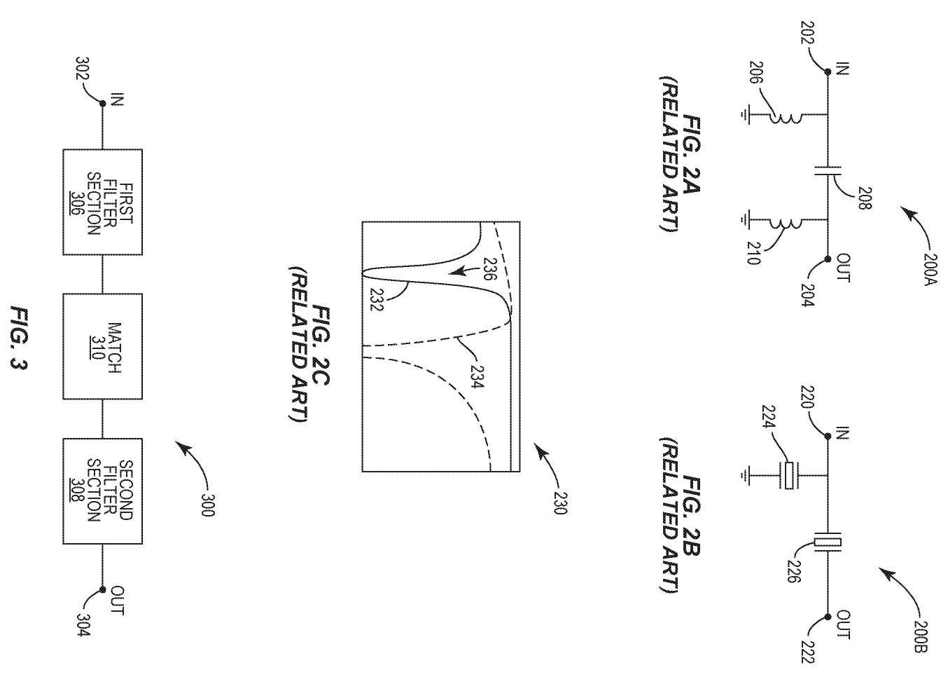

Before addressing aspects of the present disclosure, a brief overview of a Wi-Fi router and some of the issues that arise is provided with reference to FIG. 1. A discussion of filter terminology is provided with reference to FIGS. 2A-2C. A discussion of aspects of the present disclosure begins below with reference to FIG. 3.

In this regard, a communication environment 100 is illustrated in FIG. 1 with a router 102 providing wireless communication to a service area 104. Within the service area 104, there may be multiple wireless communication devices 106(1)-106(N). In general, the wireless communication devices 106(1)-106(N) may be some distance X from each other, where X is several orders of magnitude greater than a wavelength associated with operating frequencies of the router 102. That is, X is typically measured in feet or meters and the wavelengths of interest are measured in inches or centimeters.

By way of specific example, the router 102 may be a Wi-Fi router and accordingly may include transceivers 108(1), 108(2) that work within the 5 GHz frequency band and the 6 GHz frequency bands, respectively defined by the current Wi-Fi standard. While not shown, another transceiver may work in the 2.5 GHz frequency band defined by the Wi-Fi standard. The transceivers 108(1), 108(2) are coupled to antennas 110(1), 110(2) respectively through filters 112(1), 112(2) respectively. Relevantly, commercial pressures dictate that the router 102 be small and unobtrusive. Accordingly, the antennas 110(1), 110(2) may be relatively close together (typically inches or a few centimeters apart). This relatively small distance is approximately the order of magnitude of a wavelength at the frequencies of interest.

Thus, in operation when both transceivers 108(1), 108(2) are communicating (both uplink (UL) and downlink (DL)) with wireless communication devices 106(1), 106(N) concurrently on different channels within the 5 GHz and 6 GHz frequency bands, there may be cross-coupling between the antennas 110(1), 110(2). That is, a transmission from one of the transceivers 108(1), 108(2) is transmitted through the antenna 110(1), 110(2) and received at the other antenna 110(1), 110(2) and treated like a received signal by the other transceiver 108(1), 108(2). This unintended received signal generates noise within the receiving transceiver 108(1), 108(2). To clarify further, for the purposes of this example, it is assumed that the wireless communication device 106(1) operates in the 5 GHz frequency band and the wireless communication device 106(2) operates in the 6 GHz frequency band. While not labeled, the wireless communication devices 106(1), 106(2) have respective transceivers with respective filters and antennas. However, since the wireless communication devices 106(1), 106(2) operate only within one band at a time and because X is relatively large, there is only a small chance of cross-coupling at either wireless communication device 106(1), 106(2).

The presence of the cross-coupling places a burden on the filters 112(1), 112(2) to pass the frequencies of interest while blocking the unwanted adjacent

frequencies. By way of example, in a Wi-Fi system, the filter 112(1) may need approximately 60 dB of rejection for channels in the 6 GHz band. It should be appreciated that 60 dB is a loose guideline with channels that are further away needing perhaps less rejection. This requirement is complicated by the general width of the frequency band (e.g., the 6 GHz band is approximately 1.2 GHz extending from 6 GHz to 7.2 GHz) and the width of individual channels being between 20-320 MHz wide. Physics dictates that wide channels bleed more into the surrounding spectrum, so the lower 6 GHz channels will bleed heavily into the 5 GHz channels. While Wi-Fi has a specific use need, other standards and protocols may also have adjacent channels that can bleed into each other and, while the discussion below uses Wi-Fi channels as an example, the teachings of the present disclosure may be applicable to other standards such as 4G/5G cellular standards (e.g., in particular the 3GPP N104 band of the 5G standard).

FIGS. 2A-2C are provided to assist in understanding filter nomenclature. Specifically, FIGS. 2A and 2B illustrate filter stages 200A, 200B for LC circuits and acoustic filters, respectively. Thus, filter stage 200A of FIG. 2A has an input 202 and an output 204. A first shunt inductor 206 and a series capacitor 208 are coupled to the input 202, and a second shunt inductor 210 and the series capacitor 208 are coupled to the output 204. In practice, the first shunt inductor 206 and the series capacitor 208 define the lower edge of the passband of the filter stage 200A, while the second shunt inductor 210 defines the upper edge. The stage 200A is sometimes called a Π-network for its resemblance to the Greek letter Π. An equivalent (but not shown) filter stage may be found in a T-network.

FIG. 2B illustrates the filter stage 200B. The filter stage 200B has an input 220 and an output 222. A shunt acoustic resonator 224 is coupled to the input 220. A series acoustic resonator 226 is coupled in series between the input 220 and the output 222. The nature of the acoustic resonators allows the omission of the second shunt inductor.

In use, either filter stage 200A or 200B may have a frequency response as shown by graph 230 in FIG. 2C. The solid line 232 forms the lower edge, and the dotted line 234 forms the upper edge. As noted, the rejection notch 236 should approach 60 dB for the adjacent channels, meaning that the slope of the line 232 should be steep.

One approach to getting the desired rejection is to add serial filter stages (i.e., a multi-stage filter). However, this approach results in increasing insertion loss with each added stage. The insertion loss at the edges of the pass band, in particular, suffers as the number of stages increases. Thus, there remains room for improvement of filters.

Aspects of the present disclosure provide an improved filter that relies on multiple filter sections instead of strictly on multiple stages. A filter stage is defined by example above (i.e., three LC components or two acoustic components), and the authors believe that this definition of stage is generally accepted by the industry. In contrast, a filter section is a filter stage with an associated match circuit. The match circuit can be an input match circuit (i.e., at the input side of the stage) or an output match circuit (i.e., at the output side of the stage).

An exemplary multi-section filter 300 is illustrated in FIG. 3, which may be used for filter 112(1), 112(2). The multi-section filter 300 includes an input 302 and an output 304. A first filter section 306 is coupled to the input 302, and a second filter section 308 is coupled to the output 304. A match circuit 310 is serially positioned between the first filter section 306 and the second filter section 308. In this example, the first filter section 306 includes an input match circuit (not shown), and the second filter section 308 includes an output match circuit (also not shown).

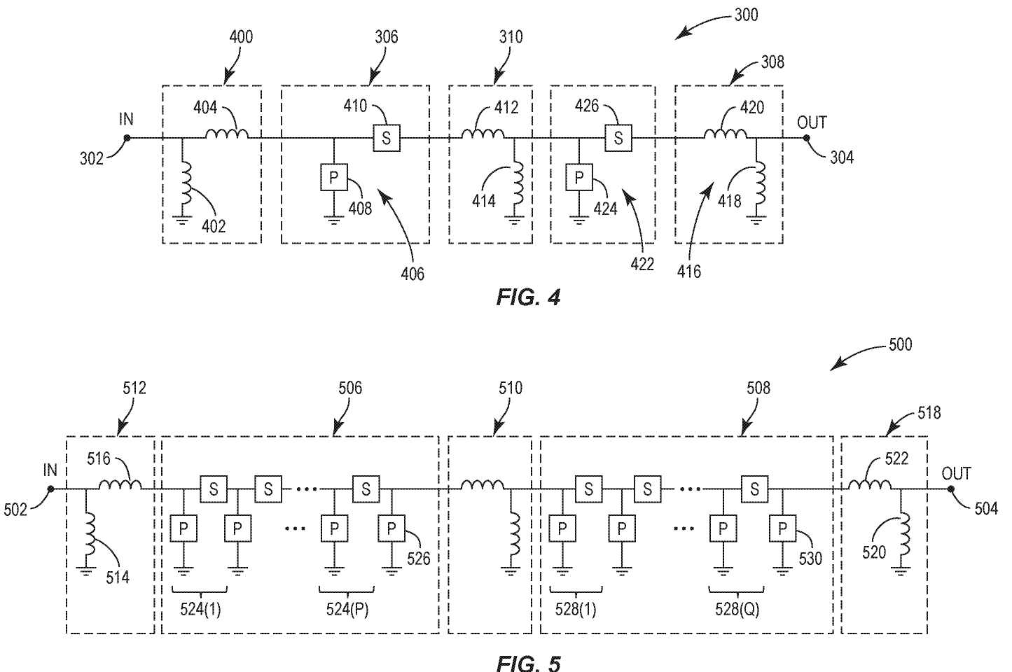

FIG. 4 expands on the multi-section filter 300. More specifically, the first filter section 306 includes an input match circuit 400 formed from a first shunt inductor 402 and a first series inductor 404. Both the first shunt inductor 402 and the first series inductor 404 are coupled to the input 302, and the first series inductor 404 is serially positioned between the input 302 and the first section 406. The first section 406 includes a first shunt acoustic resonator 408 (P used to indicate parallel and to differentiate from an “s” used for series) and a first series acoustic resonator 410 (S used to indicate series).

The match circuit 310 includes a second series inductor 412 and a second shunt inductor 414. The second filter section 308 includes an output match circuit 416 formed from a third shunt inductor 418 and a third series inductor 420. Both the third shunt inductor 418 and the third series inductor 420 are coupled to the output 304, and the third series inductor 420 is serially positioned between the second section 422 and the output 304. The second section 422 includes a second shunt acoustic resonator 424 and a second series acoustic resonator 426.

The concepts of FIGS. 3 and 4 may be expanded to a multi-stage multi-section filter 500 as shown in FIG. 5. In particular, the multi-stage multi-section filter 500 includes an input 502 and an output 504. A first multi-stage section 506 is coupled to a second multi-stage section 508 through a match circuit 510. As with the multi-section filter 300, the first multi-stage section 506 includes an input match circuit 512 having a first shunt inductor 514 and a first series inductor 516. Likewise, the second multi-stage section 508 includes an output match circuit 518 having a second shunt inductor 520 and a second series inductor 522.

With continued reference to FIG. 5, the first multi-stage section 506 also includes a plurality of sections 524(1)-524(P) with an additional last shunt acoustic resonator 526 before the match circuit 510. Similarly, the second multi-stage section 508 also includes a plurality of sections 528(1)-528(Q) with an additional last shunt acoustic resonator 530 before the output match circuit 518. Note that P does not have to equal Q, and the values of the various acoustic resonators within each section may vary as well.

Note also that there may be instances where the input match circuit 400/512 is omitted, the output match circuit 416/518 is omitted, or both. In such cases, the intervening match circuit 310/510 may be the associated match circuit and may be associated with both the first and second sections.

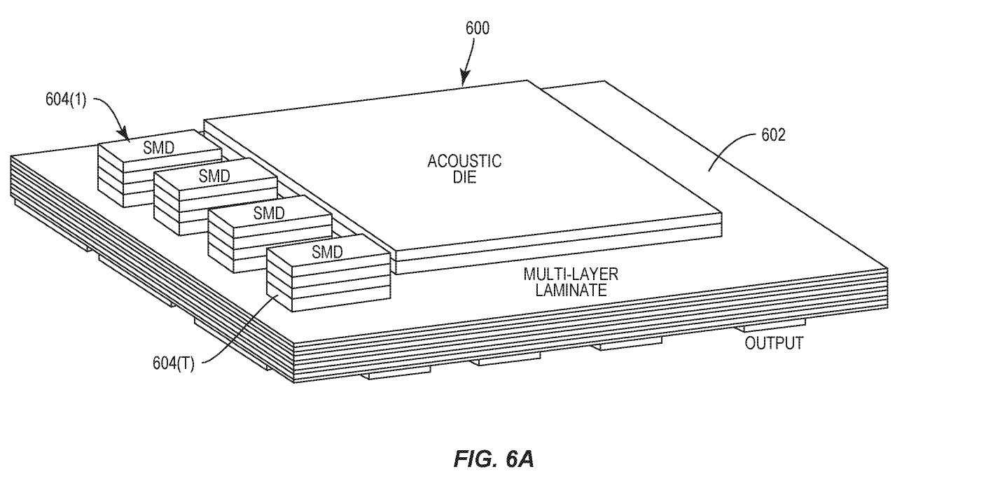

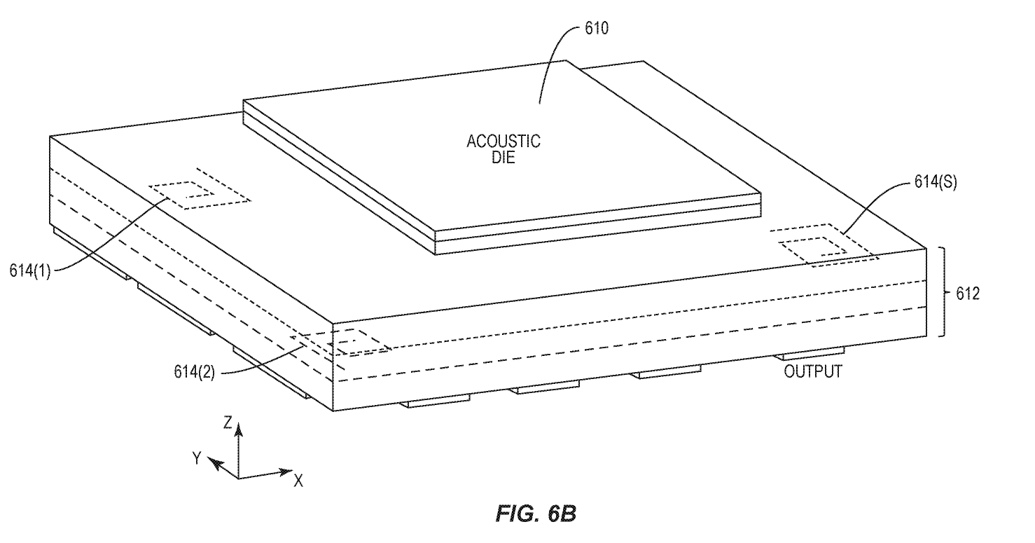

Inductors for the match circuits may be provided either through surface mounted devices as shown in FIG. 6A or as conductive traces in a laminate metallization layer associated with an acoustic die as shown in FIG. 6B. In particular, an acoustic die 600 may be positioned on a laminate metallization layer 602. Interior metal conductors (not shown) may couple the acoustic die to surface mounted devices 604(1)-604(T). In contrast, an acoustic die 610 may be positioned on a laminate metallization layer 612, and inductors 614(1)-614(S) may be positioned on metal layers within the laminate metallization layer 612.

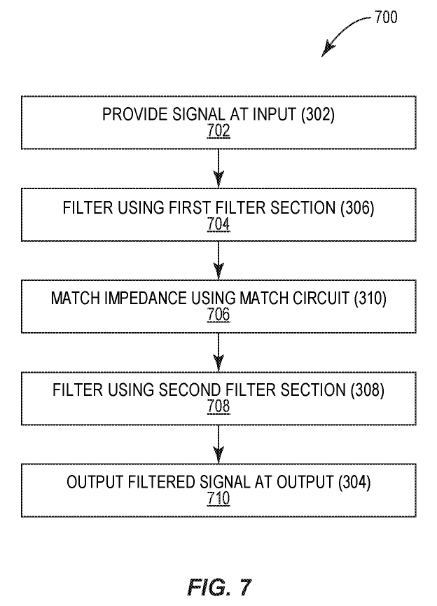

FIG. 7 provides a flowchart for a process 700 for filtering a signal using the multi-section filters of the present disclosure. In particular, the process 700 begins by providing a signal to the input 302 (block 702). The signal is filtered using a first section (block 704) and impedance matched (block 706) using match circuit 310. The signal is then filtered using the second filter section 308 (block 708). The filtered signal is then output at the output 304 (block 710).

While the exemplary use case is contemplated as being a Wi-Fi router such as router 100, it should be appreciated that other systems that have proximate antennas and cross-coupling between near frequency channels may also benefit from the present disclosure. Likewise, while Wi-Fi currently has a monolithic approach to assigning channels within the 6 GHz frequency band, there may be a time when the frequency band is subdivided and there is channel spillage between different sub-bands of the 6 GHz band. The present disclosure will also be of use in such instances. Accordingly, the Wi-Fi router discussion of the present disclosure is intended to be by way of example and not limiting.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A filter comprising:
an input;
a first filter section;
a mid-match circuit, the first filter section serially coupled between the input and the mid-match circuit;
a second filter section; and
an output, the second filter section serially coupled between the mid-match circuit and the output.

2. The filter of claim 1, wherein the first filter section comprises a first filter stage and an associated match circuit.

3. The filter of claim 2, wherein the first filter stage comprises a first shunt acoustic resonator and a first series acoustic resonator.

4. The filter of claim 2, wherein the associated match circuit comprises a first series inductor and a first shunt inductor.

5. The filter of claim 2, wherein the associated match circuit is serially positioned before the first filter stage relative to the input.

6. The filter of claim 5, wherein the second filter section comprises a second filter stage and a second associated match circuit.

7. The filter of claim 6, wherein the second associated match circuit is serially positioned after the second filter stage relative to the mid-match circuit.

8. The filter of claim 1, wherein the mid-match circuit comprises a match series inductor and a match shunt inductor.

9. The filter of claim 1, wherein the filter comprises a passband between approximately 6 GHz and 7.2 GHz.

10. The filter of claim 8, wherein the match series inductor comprises a surface-mounted device.

11. The filter of claim 8, wherein the match series inductor comprises an inductor coil positioned in a laminate metallization layer.

12. A wireless communication device comprising:
a first transceiver configured to operate at a first frequency;
a first antenna coupled to the first transceiver and configured to transmit first signals from the first transceiver;
a second transceiver configured to operate at a second frequency;
a second antenna coupled to the second transceiver and configured to transmit second signals from the second transceiver, where second signals from the second antenna may impinge on the first antenna and be received therethrough; and
a filter associated with the first antenna, the filter comprising:
an input;
a first filter section;
a mid-match circuit, the first filter section serially coupled between the input and the mid-match circuit;
a second filter section; and
an output, the second filter section serially coupled between the mid-match circuit and the output.

13. A method for filtering a signal, the method comprising:
providing a signal at an input;
filtering the signal with a first filter section;
performing an impedance match with a mid-match circuit on a filtered signal from the first filter section;
filtering a matched signal from the mid-match circuit with a second filter section; and
outputting a final signal from the second filter section.

14. The method of claim 13, wherein filtering the signal with the first filter section comprises using a first filter stage and a first associated match circuit.

15. The method of claim 14, wherein using the first filter stage comprises using a first series acoustic resonator and a first shunt acoustic resonator.

16. The method of claim 14, wherein using the first associated match circuit comprises using a first series inductor and a first shunt inductor.

17. The method of claim 13, wherein performing the impedance match with the mid-match circuit comprises using a match series inductor and a match shunt inductor.

18. The method of claim 13, wherein filtering the signal comprises generating a passband between approximately 6 GHz and approximately 7.2 GHz.

19. The method of claim 14, wherein filtering the matched signal from the mid-match circuit with the second filter section comprises using a second filter section and a second associated match circuit.

20. The method of claim 13, wherein filtering the signal comprises using a multi-stage filter.
